(19) United States
(12) Patent Application Publication
(10) Pub. No.: US 2007/0161134 A1
(43) Pub. Date: Jul. 12, 2007

(54) Method of using nanoparticles to fabricate an emitting layer of an optical communication light source on a substrate

(76) Inventors: Ching-Fuh Lin, Taipei (TW); Kuo-Jui Sun, Taipei (TW); Ping-Hung Shih, Taipei (TW); Yi-Shin Su, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/370,062

(22) Filed: Mar. 8, 2006

(30) Foreign Application Priority Data
Dec. 16, 2005 (TW) 094144709

(51) Int. Cl. H01L 21/00

(52) U.S. Cl. 438/22

(57) ABSTRACT

A method of using nanoparticles to fabricate an emitting layer of an optical communication light source on a substrate is proposed, in which a host capable of reacting with unstable ions on the surface of a rare earth ions nanomaterial is used as a carrier of nanoparticles to make the rare earth ions nanomaterial release rare earth ions, thereby forming an emitting layer that can be excited by an external current or light source to emit light.

### BACKGROUND OF THE INVENTION

1. Field of the invention

The present invention relates to a method of fabricating an emitting layer of an optical communication light source and, more particularly, to a method of using nanoparticles to fabricate an emitting layer of an optical communication light source on a substrate.

2. Description of Related Art

With continual increase of the amount of data transmission, the advantage of high transmission bandwidth of fiber communication systems becomes increasingly noticeable. The enhancement in speed of fiber communication systems, however, brings a new problem. In a high-speed transmission network, if the information at network nodes is still processed in the form of electric signal, a so-called “electronic bottleneck” (10 Gps) will occur. The nodes will become bulky and complex, and the economic benefits brought by the high-speed fiber transmission will be cancelled out by the high cost of optical-to-electric and electric-to-optical conversion. In order to solve this problem, the idea of an all optical network (AON) has been proposed. The AON, or called the wideband high-speed optical network, is based on the wavelength routing optical switching technology and the wavelength multiplexing transmission technology to realize high speed transmission and switching of information in optical domain. The signal remains an optical signal in the whole transmission process from the source node to the destination node without any optical-to-electric or electric-to-optical conversion at any node. The AON, in principle, has a signal channel from the source node to the client node that still keeps the optical form. That is, the AON is an end-to-end all-optical path without any optical-to-electric or electric-to-optical converter in between. In this way, the optical signal in the network won't be impeded by optical-to-electric or electric-to-optical conversion, and the information transmission process has not to confront the problem that the information processing speed of electronic components is difficult to increased. The erbium doped fiber amplifiers (EDFA) is the core technology for building the AON. The band from 1300 nm to 1500 nm is an important wavelength range of fiber communication network. Because the optical fiber has a wider bandwidth with low attenuation within the 1550 nm window, when integrated with the wavelength division and dispersion compensation technology, the EDFA becomes the best method for exploring the potential bandwidth capacity of optical fiber.

However, the present fabrication process of EDFA still cannot be integrated with the present IC fabrication process. Moreover, the EDFA has a too-large volume.

The erbium doped waveguide amplifier working in the 1530 nm optical communication band is another promising technology after the successful development of EDFA and semiconductor optical amplifier (SOA). The erbium doped waveguide amplifier has the advantages of high gain per unit length, compact structure, small size, and flexible application in limit space. The waveguide structure can confine the energy of pumping light in a region with a very small cross section and a larger length to obtain a very high optical gain per unit length, about 100 times that of the fiber structure. Compared to the EDFA applied in the present optical communication systems, the erbium doped waveguide amplifier has its specific advantages. Because the erbium doped waveguide amplifier requires no erbium doped fiber of several meters long, it can provide a better performance/price ratio than the EDFA.

The present fabrication methods of erbium doped waveguide amplifier can generally be categorized into ion implantation, solid phase epitaxy (SPE), ion exchange, sol-gel, and so on.

Today's smallest erbium doped glass waveguide amplifier module can acquire a gain of 15 dB at the 1535 nm window, and has a volume of 130 mm×11 mm×6 mm. This integrated fabrication process, however, has also drawbacks. In order to acquire the best performance, other functions except the signal amplification function has to be realized in undoped material, hence increasing potential failure rate caused by bonding or adhesion of chip. Of course, the doped waveguides and the undoped waveguides can be integrated on the same substrate to solve this problem, but the process will be very complex with present techniques.

Fabricating the erbium doped waveguide amplifier on a silicon (Si) substrate can solve the above problem. Nowadays, other Si-based erbium doped components are predominantly fabricated by means of assembly, molecular beam epitaxy (MBE) or ion implantation. But all the above methods have the disadvantages of too large volume, high fabrication cost per unit area, slow growth rate, and so on. Besides, the ion implantation method has also the drawbacks of difficult control of ion implantation concentration and easy damage to the substrate. Furthermore, the indirect bandgap of Si makes the light emission wavelength not suitable for optical communication.

Accordingly, the present invention aims to propose a method of using nanoparticles to fabricate an emitting layer of an optical communication light source on a substrate to solve the above problems in the prior art.

### SUMMARY OF THE INVENTION

An object of the present invention is to provide a method of using nanoparticles to fabricate an emitting layer of an optical communication light source on a substrate, which makes use of a low-cost, economic, fast and integrated way to fabricate an emitting layer on a Si semiconductor for emitting light at the communication band.

The present invention is not limited by the indirect bandgap of Si, and can emit light at the communication band from the Si surface. The fabrication process is economic and fast, hence greatly saving the cost.

The present invention also has the advantages of small volume, no damage to the substrate, easy control of the doping concentration, easy integration with other components on the Si substrate, and large gain per unit length. The present invention therefore has high practicability.

Moreover, the emitting layer fabricated by the present invention can be used as an emitting layer in an electronic component for producing a light signal.

The present invention provides a method of using nanoparticles to fabricate an emitting layer of an optical communication light source on a substrate, which comprises the steps of: providing a clean substrate; mixing at least a rare earth ions nanomaterial with a liquid host to form a doped liquid host; coating the doped liquid host on the substrate to form a doped liquid host layer; solidifying the doped liquid host layer to form a doped solid state host layer; and heating the doped solid state host layer to form an emitting layer.

### BRIEF DESCRIPTION OF THE DRAWINGS

The various objects and advantages of the present invention will be more readily understood from the following detailed description when read in conjunction with the appended drawing, in which:

FIG. 1 is a flowchart of the present invention;

FIG. 2 is a diagram of a component fabricated by the present invention;

FIG. 3(a) is an energy band diagram showing continuous tunneling and light emission of electrons at Er³⁺ energy levels in the emitting layer;

FIG. 3(b) is an energy band diagram showing how added silver (Ag) nanoparticles enhance the tunneling probability of electrons in the emitting layer;

FIG. 4(a) is a current vs. voltage diagram of two components doped with different percentages of Ag nanoparticles;

FIG. 4(b) is a current vs. voltage diagram of a component without Ag nanoparticles doped;

FIG. 5 is a diagram showing variation of the photoluminescence spectrum of an emitting layer after the thickness of the emitting layer is changed;

FIG. 6 is a diagram showing variation of the photoluminescence spectrum of an emitting layer after the agitation duration is changed;

FIG. 7 is a flowchart according to another embodiment of the present invention;

FIG. 8 is a spectrum diagram measured by a component that undergoes multi-stage thermal processing;

FIG. 9 is a comparison diagram of light emission efficiency with different percentages of Ag nanoparticles added into the host;

FIG. 10 is a comparison diagram of light emission intensity with different percentages of Si nanoparticles added;

FIG. 11 is a comparison diagram of light emission intensity with and without indium oxide (In₂O₃) nanoparticles added;

FIG. 12 is a comparison diagram of light emission intensity with different percentages of aluminum (Al) nanoparticles added;

FIG. 13 is a comparison diagram of light emission intensity with and without ytterbium oxide (Yb₂O₃) nanoparticles added;

FIG. 14 is a diagram showing how the pumping power and intensity vary with the relative pumping length at a photoluminescence wavelength of 1530 nm; and

FIG. 15 is diagram showing how the intensity at a photoluminescence wavelength of 1530 nm varies with the pumping length when excited by a 980 nm laser.

### DETAILED DESCRIPTION OF THE PREFERRED EMBODIMENTS

The present invention proposes a method of using nanoparticles to fabricate an emitting layer of an optical communication light source on a substrate. In the present invention, nanomaterial capable of releasing rare earth ions such as erbium, praseodymium and ytterbium is first mixed in a methanol solution with dispersed SiO₂ nanoparticles, a P₂O₅ solution or a spin on glass (SOG) solution and then coated on a substrate to form an emitting layer capable of emitting light at the communication band. The present invention makes use of photoluminescence to promote rare earth elements to excited states. When there is a proper forward bias between the emitting layer and the semiconductor substrate, electrons can cross this emitting layer to the other side through the tunneling effect. In other words, the present invention can make use of electroluminescence to promote rare earth elements to excited states. When electrons drop to lower energy levels, photons can be emitted.

Besides, the present invention further utilizes the surface effect of so-called nanomaterial. That is, the ratio of the number of surface atoms to the number of total atoms will rise abruptly with the decrease of particle size, and the surface energy and surface tension increase therewith, hence resulting in changes in physical and chemical properties of nanomaterial. Speaking more clearly, when the diameter of particles decreases to very small, the number of surface atoms of particles and the specific surface area will increase substantially. Under this situation, the crystal environment where the surface atoms are and the binding energy of the surface atoms will be different from those of internal atoms. The surface atoms will have higher unsaturated property and chemical activity as compared to internal atoms. Therefore, surface atoms of particles will very easily react with other atoms.

In the fabrication process adopted by the present invention, the selected excited ions sources are rare earth ion nanoparticles. They can be the erbium element, the ytterbium element or their oxides. The substrate can be a P-type, N-type or undoped Si or III-V compound semiconductor, or a quartz, a glass or a glass coated with tin-doped In₂O₃. The selected host of excited ions can be an SOG solution, a methanol solution with dispersed SiO₂ nanoparticles or a P₂O₅ solution. Moreover, the liquid host can be added with any material that facilitates precipitation of ions of the rare earth ions nanomaterial such as a KOH solution, a phosphoric acid solution, and so on.

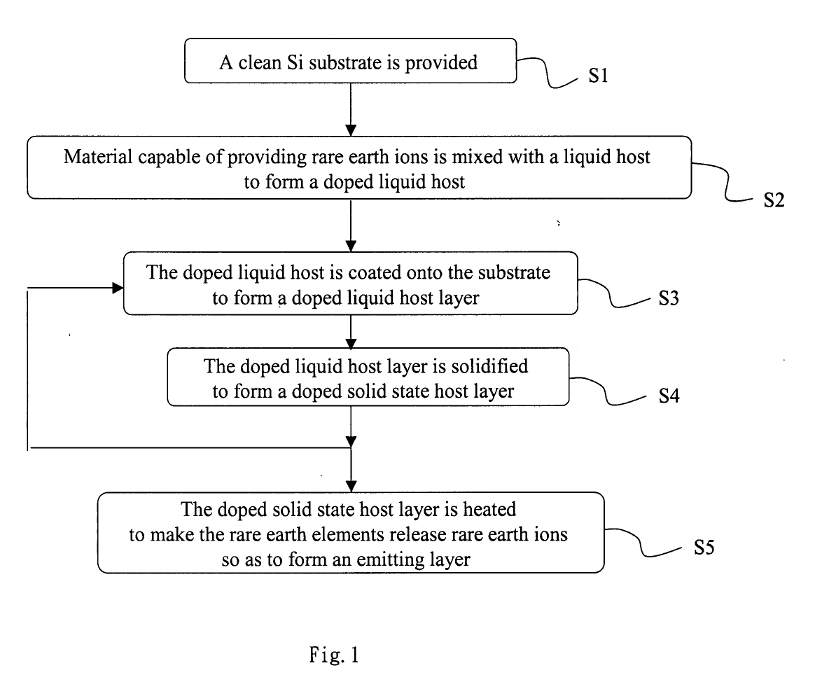

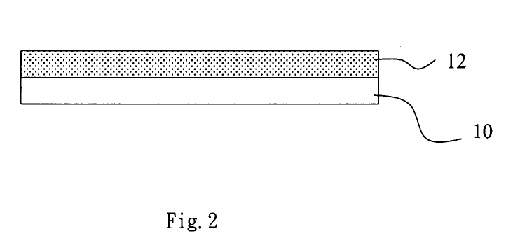

FIG. 1 is a flowchart of the present invention. First, a clean Si substrate is provided (Step S1). Material capable of providing rare earth ions such as erbium oxide (Er₂O₃) nanoparticles (particle diameter: 1 nm˜100 nm) is mixed with a liquid host such as an SOG solution with a weight ratio of 1:3˜1:7 to form a doped liquid host (Step S2). When the rare earth ions nanomaterial contains Er₂O₃ nanoparticles and the liquid host is a P₂O₅ solution, the weight of the liquid host is 0.3˜0.7 times that of the Er₂O₃ nanoparticles. The choice of this ratio depends on the expected light emission efficiency and the particle diameter of nanoparticles used. Besides, during the mixing process of the liquid host and the nanoparticles, supersonic vibration can be used for uniform mixing so as to reduce the agglomerating force of nanoparticles and disperse nanoparticles to have a larger surface area. Next, the doped liquid host is coated onto the Si substrate to form a doped liquid host layer on the Si substrate (Step S3). It should be noted that the host still has fluidity after this step. The doped liquid host layer is subsequently solidified to remove organic solvent in the liquid host and form a doped solid state host layer (Step S4). The solidification baking temperature can be 70˜90° C. (e.g., 80 C.). According to the required luminosity, several doped solid state host layers can be stacked on the doped solid state host layer (repeating Step S3 and Step S4) to increase the total thickness of doped solid state host layer. Finally, the substrate is heated to make unstable rare earth elements on the surface of the rare earth nanoparticles react with the host to release rare earth ions and form an emitting layer (Step S5). The whole structure is shown in FIG. 2, which comprises a substrate 10 and an emitting layer 12 on the substrate 10. The emitting layer 12 comprises at least a doped solid state host layer. A plurality of rare earth ions is dispersed in the doped solid state host layer. The rare earth ions are released by nanoparticles that can provide rare earth ions and are mixed in the host.

The above fabrication process is only an embodiment of the present invention. The manners of fabrication and choices of material are not limited to the above embodiment. In other words, the object of the present invention can be accomplished by combining rare earth elements, a solution such as a methanol solution with dispersed SiO₂ nanoparticles, a P₂O₅ solution or an SOG solution, and a substrate.

After increasing the concentration of erbium ions (Er³⁺) or adding Ag nanoparticles in the emitting layer, when the thickness is controlled below 500 Å, electrons can undergo several times of tunneling and light emission to cross the emitting layer, reach the anode, and thus form a current. The drawback of bad conductivity of Er₂O₃ can therefore be compensated. This continuous tunneling and light emission process is the mechanism of electroluminescence.

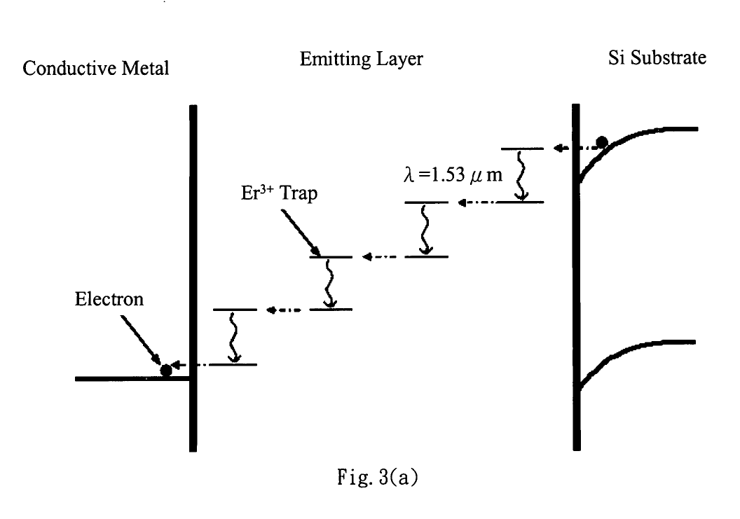

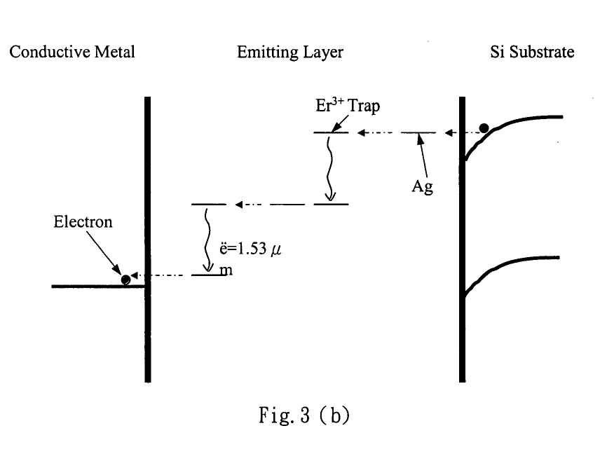

FIG. 3(a) is an energy band diagram showing continuous tunneling and light emission of electrons at Er³⁺ energy levels in the emitting layer. FIG. 3(b) is an energy band diagram showing how added Ag nanoparticles enhance the tunneling probability of electrons in the emitting layer.

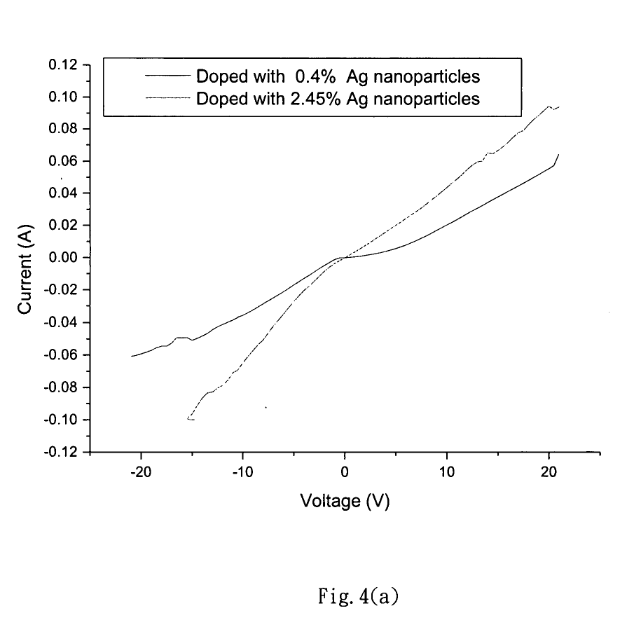

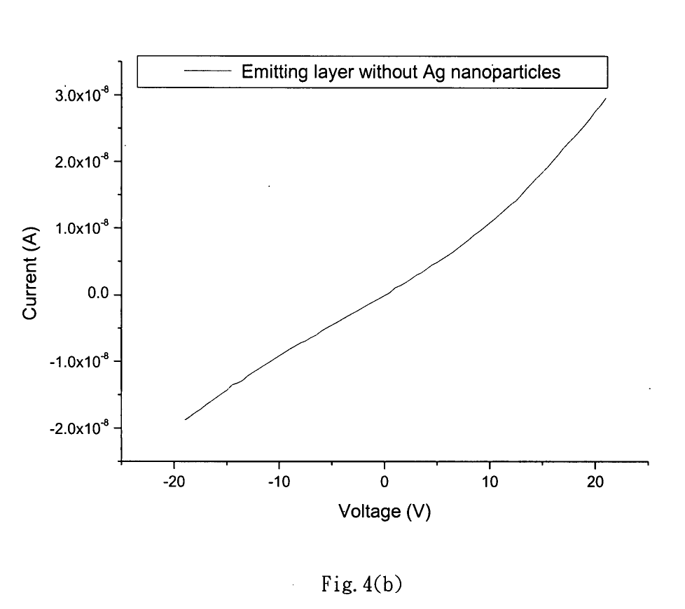

FIG. 4(a) is a current vs. voltage diagram of two components doped with different percentages of Ag nanoparticles. FIG. 4(b) is a current vs. voltage diagram of a component without Ag nanoparticles doped. Through comparison, it is confirmed that adding Ag nanoparticles in the emitting layer can greatly enhance the conductivity.

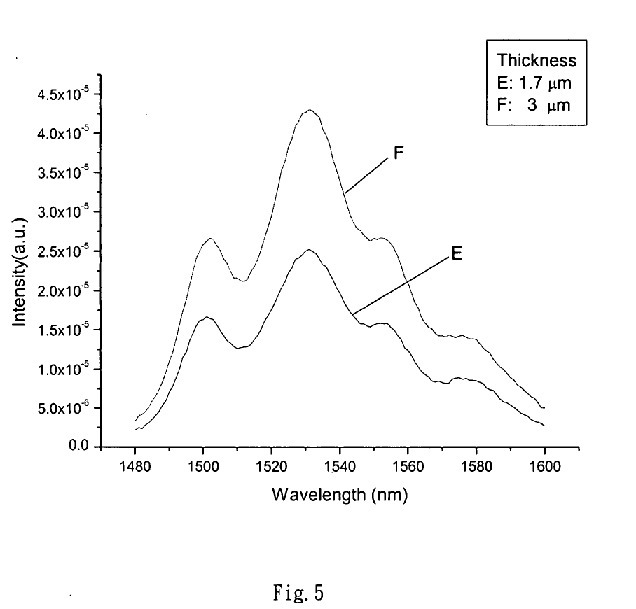

FIG. 5 is a diagram showing variation of the photoluminescence spectrum of an emitting layer after the thickness of the emitting layer is changed.

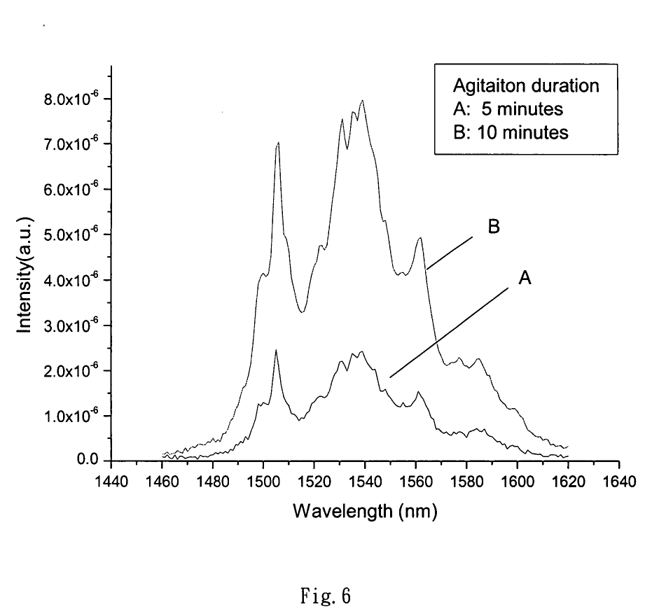

FIG. 6 is a diagram showing variation of the photoluminescence spectrum of an emitting layer after the agitation duration is changed. In the step of fabricating the doped liquid host, a supersonic vibrator is used to change the degree of uniformity when mixing the doping nanoparticles in the liquid host. From the figure, we know that if the vibration time increases, the nanoparticles will disperse more uniformly and react more thoroughly in the liquid host. The preferred vibration time is 10˜30 minutes.

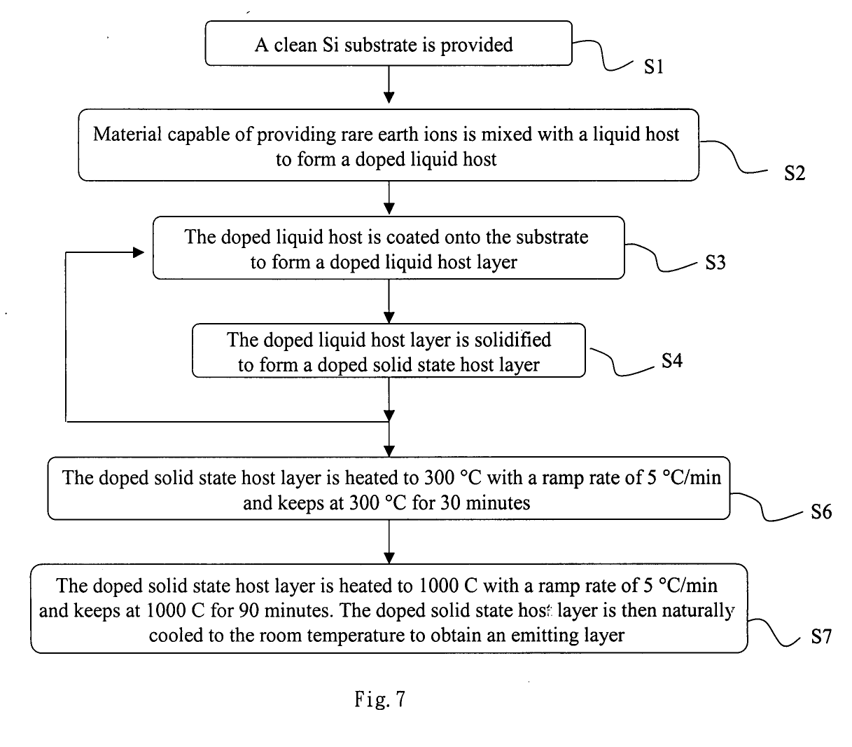

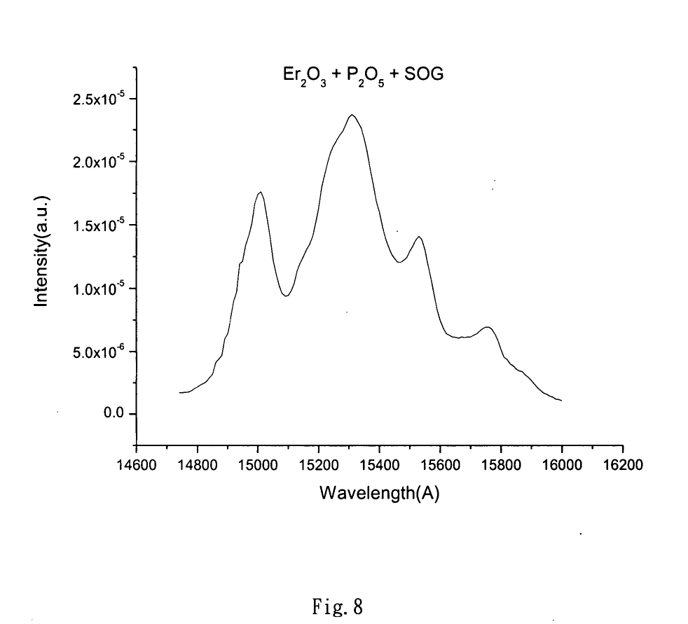

Moreover, when the liquid host has phosphorous oxide (e.g., P₂O₅), the heating temperature and time can be controlled to change the reaction mechanism so as to enhance the light emission efficiency. FIG. 7 is a flowchart according to another embodiment of the present invention. As shown in FIG. 7, the temperature and time of Step S5 are properly changed to make P₂O₅ react with the SOG to form phosphate glass. During subsequent high temperature (1000° C.), Er₂O₃ can more easily release erbium ions. This can reduce aggregation of rare earth ions on the substrate, hence enhancing the light emission efficiency. The modified heating step is as follows. First, the substrate is heated to 300° C. with a ramp rate of 5° C./min and keeps at 300° C. for 30 minutes (Step S6). The substrate is then heated to 1000 C. with the same ramp rate and keeps at 1000 C. for 90 minutes (Step S7). Next, the substrate is naturally cooled to the room temperature to obtain a light emitting component. The reason why the substrate is first heated to 300 C. is to make P₂O₅ react with the SOG to form phosphate glass so that Er₂O₃ can more easily release erbium ions at 1000 C. This way of heating can reduce aggregation of rare earth ions on the substrate, hence enhancing the light emission efficiency. FIG. 8 is a spectrum diagram measured by a component that undergoes multi-stage thermal processing.

Embodiments in which an appropriate amount of nanoparticles capable of enhancing the light emission efficiency such as Ag, Si, Al, In₂O₃ and Yb₂O₃ when added into the host will be exemplified with experiments below.

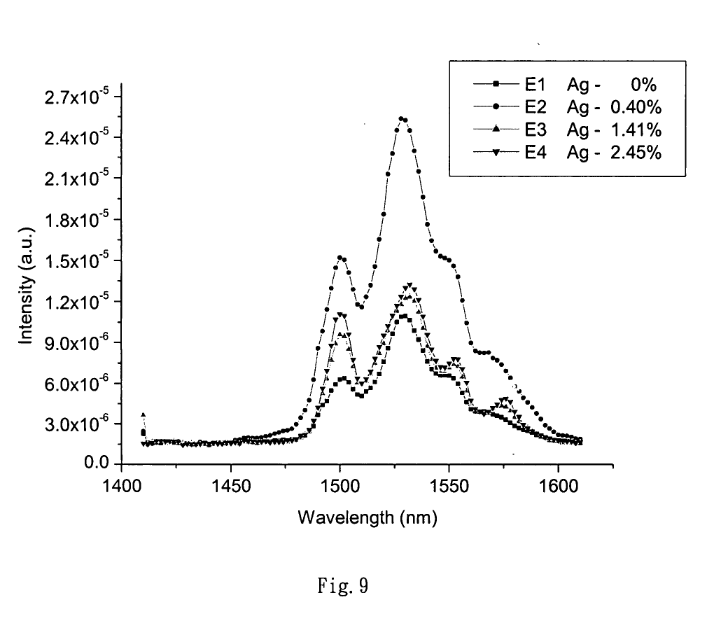

FIG. 9 is a comparison diagram of light emission efficiency with different percentages of Ag nanoparticles added into the host. From the figure, we know that adding Ag nanoparticles has the opportunity of changing the surface structure of the substrate during the heating process. Moreover, Ag ions can transfer energy to erbium ions to enhance the light emission efficiency after absorbing excitation energy. In FIG. 9, when the particle diameter of In₂O₃ nanoparticles is 30˜50 nm and that of Ag nanoparticles is 15˜35 nm and the weight of Ag nanoparticles added into the host is 0.01˜0.04 times that of In₂O₃ nanoparticles, it is found that adding Ag nanoparticles can apparently enhance the luminous intensity of the emitting layer.

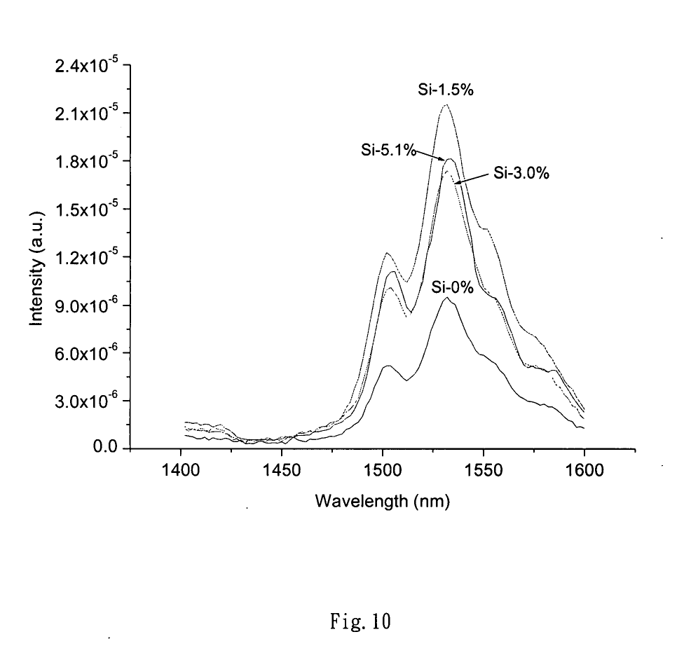

FIG. 10 is a comparison diagram of light emission intensity with different percentages of Si nanoparticles added. Through an action mechanism similar to that of Si nanocrystal, Si nanoparticles can help enhancing the excitation efficiency of rare earth elements such as erbium ions, thereby increasing the luminous intensity of the emitting layer. From the figure, it is found that an optimum effect can be obtained when the weight of added Si nanoparticles (with a particle diameter of 20˜40 nm) is 0.06˜0.12 times that of Er₂O₃ nanoparticles (with a particle diameter of 30˜50 nm).

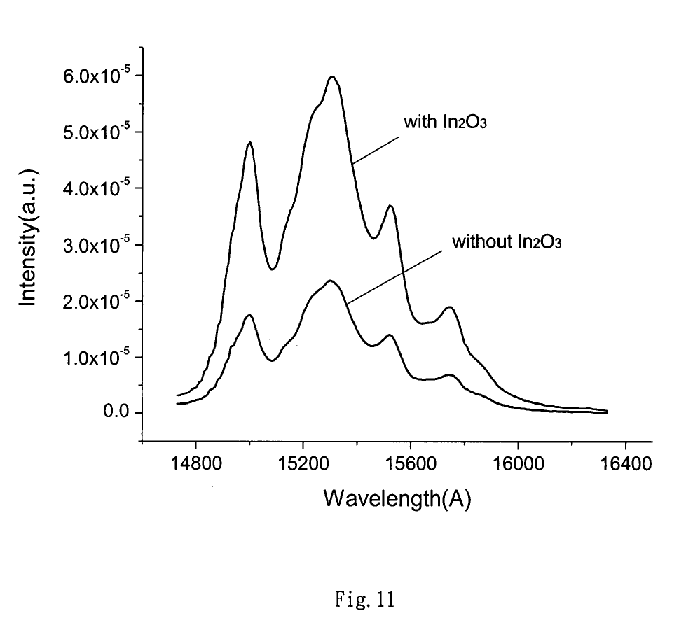

FIG. 11 is a comparison diagram of light emission intensity with and without In₂O₃ nanoparticles added. From the figure, it is found that adding In₂O₃ nanoparticles can apparently enhance the luminous intensity of the light emission efficiency. Moreover, it is preferred that the weight of added In₂O₃ nanoparticles (with a particle diameter of 30˜50 nm) is 0.2˜0.4 times that of Er₂O₃ nanoparticles (with a particle diameter of 30˜50 nm).

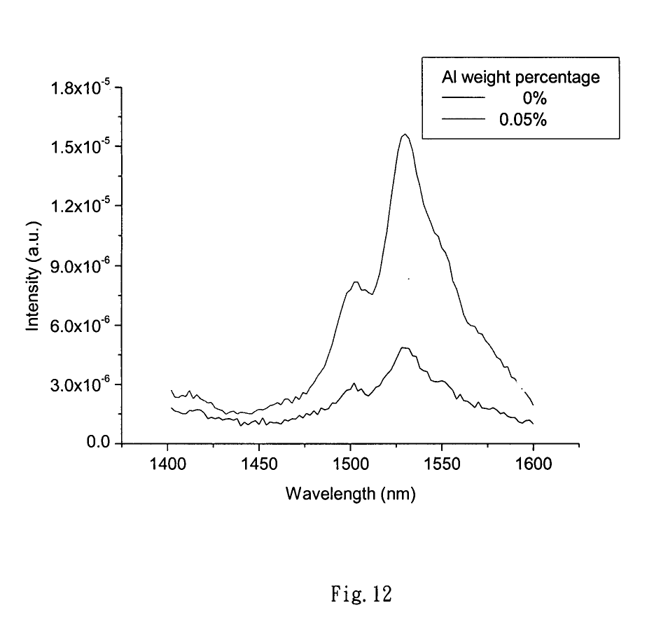

When Al nanoparticles are added into the host, the Al nanoparticles will be oxidized into Al oxide. Under such a condition, the solubility of rare earth elements can be enhanced, and there will be more rare earth ions per unit volume and thus a higher luminous intensity per unit volume. FIG. 12 is a comparison diagram of light emission intensity with different percentages of Al nanoparticles added. It is found from the figure that the light emission efficiency can be enhanced when the weight of added Al nanoparticles (with a particle diameter of 15˜35 nm) is 0.003˜0.007 times that of Er₂O₃ nanoparticles (with a particle diameter of 30˜50 nm).

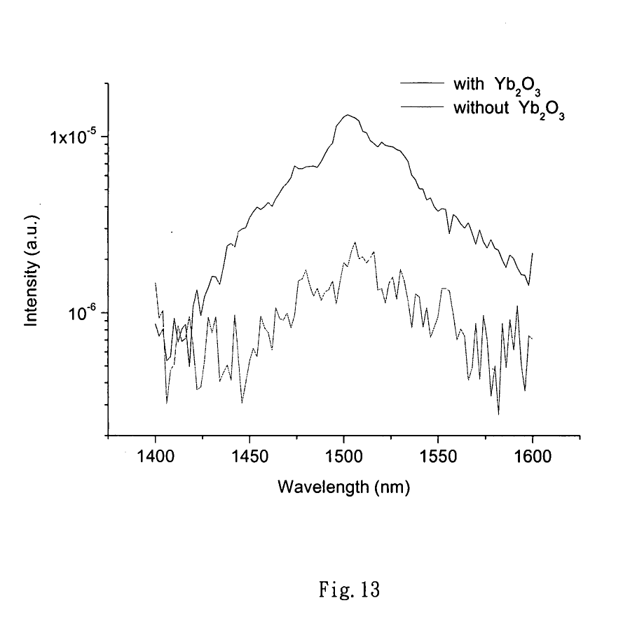

Besides, adding Yb₂O₃ nanoparticles can effectively enhance the luminous intensity of the emitting layer by an order of magnitude, as shown in FIG. 13. The optimum effect can be obtained when the weight of added Yb₂O₃ nanoparticles (with a particle diameter of 30˜50 nm) is 1˜5 times that of Er₂O₃ nanoparticles (with a particle diameter of 30˜50 nm).

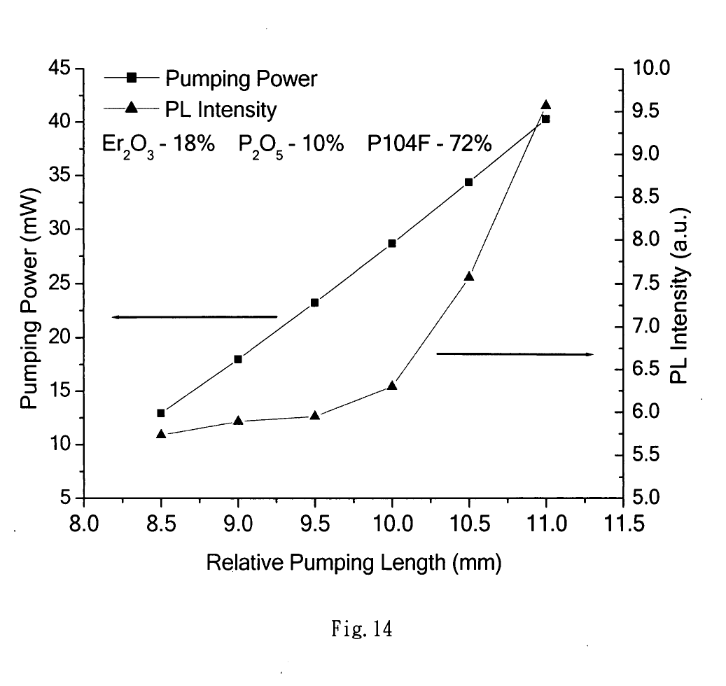

FIG. 14 is a diagram showing how the pumping power and the photoluminescence intensity vary with the relative pumping length at a photoluminescence wavelength of 1530 nm. Because the relation between the pumping power and the pumping length of the pump laser is linear but the relation between the photoluminescence intensity and the pumping length is nonlinear, there certainly exists an optical gain.

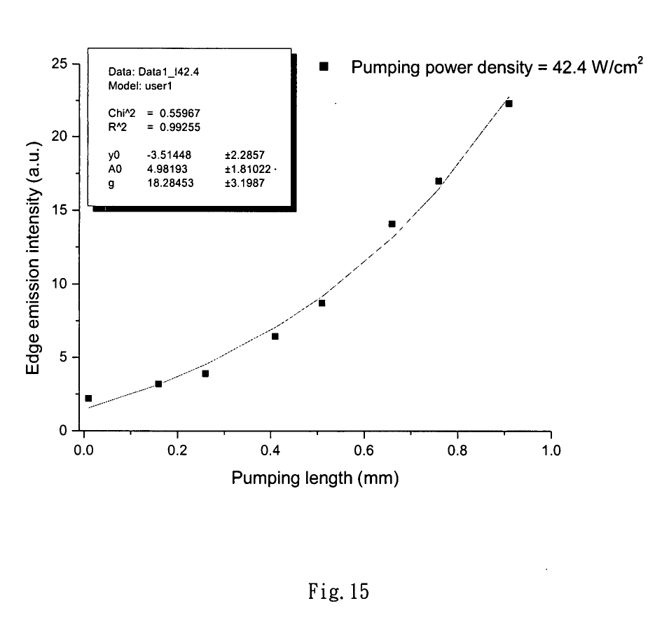

FIG. 15 is diagram showing how the intensity at a photoluminescence wavelength of 1530 nm varies with the pumping length when excited by a 980 nm laser. Utilizing exponential fitting experiment data, the optical gain is found to be 18 cm⁻¹ or 36 dB/cm. There are two reasons that account for such a high optical gain. First, the Er₂O₃ nanoparticles contribute high concentration erbium ions. Second, ytterbium ions provided by the Yb₂O₃ nanoparticles help enhancing the energy absorption efficiency of erbium ions.

Compared to present erbium doped waveguide amplifiers with an optical gain of about 0.6˜4 dB/cm, the erbium doped emitting layer of the present invention can provide higher optical gains. Moreover, the present invention also provides a method for fabricating small-volume high-gain optical amplifiers. Because the fabrication process is simple, and can be realized on a P-type, N-type or undoped Si or III-V compound semiconductor, or a quartz, a glass or a glass coated with tin-doped In₂O₃, the application range can be substantially expanded. Furthermore, because Si can be selected as the substrate of the present invention, the difficulty of integration with present Si ICs can be substantially reduced. Therefore, Si chips not only can apply to electronic products, but can also be used as light emitting components at communication bands. Monolithic integration of electronic chips and light emitting components can further expand the application range of Si chips and Si material, and can even become the core technology of further AON. If matched with a-resonance structure, the emitting layer can also be used as the active material of erbium doped lasers operating at a wavelength of 1530 nm. Because this laser wavelength is safe to human eyes and is within the communication window, it can be applied in the fields of communication, biochemical detection, and range finder.

To sum up, the erbium doped emitting layer fabricated by the present invention is another novel optoelectronic device after semiconductor optical amplifier (SOA) and erbium doped fiber amplifier (EDFA). The present invention has the advantages of small volume, large gain per unit length, low cost and simple fabrication process, and can be directly integrated with the present IC industry, hence having high practicability.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

I claim:

1. A method of using nanoparticles to fabricate an emitting layer of an optical communication light source on a substrate comprising the steps of:
providing a clean substrate;
mixing at least a rare earth ions nanomaterial with a liquid host with a ratio of 1:1˜1:20 to form a doped liquid host;
coating said doped liquid host on said substrate to form a doped liquid host layer;
solidifying said doped liquid host layer to form a doped solid state host layer; and
heating said doped solid state host layer to make said rare earth nanomaterial release rare earth ions to form an emitting layer.

2. The method as claimed in claim 1, wherein said liquid host can be a solution with dispersed SiO₂ nanoparticles, a P₂O₅ solution or an SOG solution.

3. The method as claimed in claim 1, wherein said rare earth ions nanomaterial can be rare earth element nanoparticles, rare earth compound nanoparticles or rare earth ion nanoparticles.

4. The method as claimed in claim 1, wherein when said rare earth ions nanomaterial contains Er₂O₃ nanoparticles and said liquid host is a P₂O₅ solution, the weight of said liquid host is 0.3˜0.7 times that of said rare earth ions nanomaterial.

5. The method as claimed in claim 1, wherein when said rare earth ions nanomaterial contains Er₂O₃ nanoparticles and said liquid host is an SOG solution, the weight of said liquid host is 3˜7 times that of said rare earth ions nanomaterial.

6. The method as claimed in claim 1, wherein said liquid host is added with any material that facilitates precipitation of ions of said rare earth ions nanomaterial such as a KOH solution, a phosphoric acid solution, and so on.

7. The method as claimed in claim 1, wherein said liquid host is added with any nanoparticles that can increase the light emission efficiency such as Ag nanoparticles, Si nanoparticles, Al nanoparticles, In₂O₃ nanoparticles, Yb₂O₃ nanoparticles, and so on.

8. The method as claimed in claim 7, wherein when the nanoparticles added into said liquid host to increase the light emission efficiency are Ag nanoparticles and said rare earth ions nanomaterial contains Er₂O₃ nanoparticles, the weight of said Ag nanoparticles is 0.01˜0.04 times that of said Er₂O₃ nanoparticles.

9. The method as claimed in claim 7, wherein when the nanoparticles added into said liquid host to increase the light emission efficiency are Si nanoparticles and said rare earth ions nanomaterial contains Er₂O₃ nanoparticles, the weight of said Si nanoparticles is 0.06˜0.12 times that of said Er₂O₃ nanoparticles.

10. The method as claimed in claim 7, wherein when the nanoparticles added into said liquid host to increase the light emission efficiency are In₂O₃ nanoparticles and said rare earth ions nanomaterial contains Er₂O₃ nanoparticles, the weight of said In₂O₃ nanoparticles is 0.2˜0.4 times that of said Er₂O₃ nanoparticles.

11. The method as claimed in claim 7, wherein when the nanoparticles added into said liquid host to increase the light emission efficiency are Al nanoparticles and said rare earth ions nanomaterial contains Er₂O₃ nanoparticles, the weight of said Al nanoparticles is 0.003˜0.007 times that of said Er₂O₃ nanoparticles.

12. The method as claimed in claim 7, wherein when the nanoparticles added into said liquid host to increase the light emission efficiency are Yb₂O₃ nanoparticles and said rare earth ions nanomaterial contains Er₂O₃ nanoparticles, the weight of said Yb₂O₃ nanoparticles is 1˜5 times that of said Er₂O₃ nanoparticles.

13. The method as claimed in claim 8, wherein the size of said Er₂O₃ nanoparticles is 30˜50 nm, and the size of said Ag nanoparticles is 15˜35 nm.

14. The method as claimed in claim 9, wherein the size of said Er₂O₃ nanoparticles is 30˜50 nm, and the size of said Si nanoparticles is 20˜40 nm.

15. The method as claimed in claim 10, wherein the size of said Er₂O₃ nanoparticles is 30˜50 nm, and the size of said In₂O₃ nanoparticles is 30˜50 nm.

16. The method as claimed in claim 11, wherein the size of said Er₂O₃ nanoparticles is 30˜50 nm, and the size of said Al nanoparticles is 15˜35 nm.

17. The method as claimed in claim 12, wherein the size of said Er₂O₃ nanoparticles is 30˜50 nm, and the size of said Yb₂O₃ nanoparticles is 15˜35 nm.

18. The method as claimed in claim 1, wherein before said step of heating said doped solid state host layer, a doped liquid host layer can be further coated on said doped solid state host layer and then be solidified to form another doped solid state host layer.

19. The method as claimed in claim 1, wherein said step of mixing said rare earth ions nanomaterial and said liquid host can be accomplished by supersonic vibration to achieve uniform mixing.

20. The method as claimed in claim 1, wherein said step of heating said doped solid state host layer can be accomplished by singly or mixedly using a furnace, the IR rapid thermal annealing, and the high energy laser annealing.

21. The method as claimed in claim 1, wherein said step of heating said doped solid state host layer can be accomplished by a single-stage heating at a single temperature or a multi-stage heating at different temperatures.

22. The method as claimed in claim 1, wherein said step of heating said doped solid state host layer includes first heating said substrate at 300° C. for 30 minutes and then heating said substrate at 1000° C. for 90 minutes.

23. The method as claimed in claim 1, wherein said substrate can be a P-type, N-type or undoped Si or III-V compound semiconductor, or a quartz, a glass or a glass coated with tin-doped In₂O₃.

24. The method as claimed in claim 1, wherein the rare earth element of said rare earth ions nanomaterial is erbium, praseodymium or ytterbium.

25. The method as claimed in claim 1, wherein the solidification temperature is 70˜90° C.
